(19) United States
(12) Patent Application Publication
(10) Pub. No.: US 2006/0157791 A1
(43) Pub. Date: Jul. 20, 2006

(54) ESD protection device

(75) Inventors: Jian-Hsing Lee, Pu-Tzu City (TW); Fu-Liang Yang, Hsinchu (TW); Chien-Chao Huang, Hsinchu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/037,868

(22) Filed: Jan. 18, 2005

(51) Int. Cl. H01L 23/62

(52) U.S. Cl. 257/357

(57) ABSTRACT

An ESD protection device. A first-type well is formed on an insulating layer. First and second second-type doped regions are formed on the first-type well. A first body-tie region is formed on the first-type well and is connected to one side of the first and the second second-type doped regions. A polysilicon gate layer is formed on the first-type well and the body-tie region, and is located between the first and the second second-type doped regions. The first first-type doped region is connected to the first body-tie region. The second first-type doped region is formed on the first-type well.

### BACKGROUND OF THE INVENTION

The present invention relates to an electrostatic discharge (ESD) protection device and in particular to an ESD protection device for positive and negative ESD protection.

### DESCRIPTION OF THE RELATED ART

Electrostatic discharge (ESD) is a common phenomenon that occurs during handling of semiconductor integrated circuit (IC) devices. Electrostatic charges may accumulate and cause potentially destructive effects on an IC device. ESD stress can typically occur during a testing phase of IC fabrication, during installation of the IC onto a circuit board, as well as during use of equipment in which the IC has been installed. Damage to a single IC due to poor ESD protection in an electronic device can partially or sometimes completely impede its operation.

There are several ESD stress models based on the reproduction of typical discharge pulses to which the IC may be exposed during manufacturing or handling. Three standard models, known as the Human Body Model (HBM), Machine Model (MM), and Charged Device Model (CDM) have been proposed. The human-body model is set forth in U.S. Military Standard MIL-STD-883, Method 3015.6. The military standard models the electrostatic stress produced on an IC device when a human carrying electrostatic charges touches the lead pins of the IC device. The machine model is set forth in Industry Standard EIAJ-IC-121, which describes the electrostatic stress produced on an IC device when a machine carrying electrical charge contacts the lead pins of the IC device. The charged device model describes the ESD current generated when an IC already carrying electrical charge is grounded while being handled.

Thin film, co-planar integrated circuits employing silicon-on-insulator (SOI) or silicon-on-sapphire (SOS) CMOS technology typically include a semiconductor (silicon) layer, which is disposed atop a substrate-supported dielectric (silicon dioxide) layer, with the side wall perimeter of the devices bounded by an air or (oxide) dielectric layer. The air or oxide dielectric layer helps provide lateral isolation between adjacent devices.

This semiconductor structure typically includes a body/channel region disposed between and immediately contiguous with respective source and drain regions. Overlying the channel/body region and extending onto the surrounding support substrate is a doped polysilicon gate layer, which is insulated from the semiconductor material by a thin dielectric layer (e.g., gate oxide). The air or oxide dielectric layer that bounds the side wall perimeter of the device typically extends under the polysilicon gate layer and forms the side wall of the channel/body region. To reduce the resistivity of the polysilicon gate layer and the source and drain regions, a silicide layer is often provided over the polysilicon gate, and over the source and drain regions.

U.S. Pat. No. 6,404,269 to Voldman discloses an NFET B/G-C diode. FIG. 1 of the patent illustrates the NFET B/G-C diode 10 that is formed from a silicon-on-insulator (SOI) MOSFET having an isolation region 24, buried oxide 12, and silicon substrate 14. Two N+ regions are formed, a source region 16 and a drain region 17, on a P-type body region 18. A gate electrode 22 overlies a gate insulator 21 and defines the gate of the MOSFET 30. A surface channel lies below gate insulator 21 and on the surface of the P-type region 18, wherein the P-type region is also known as the channel. The source 36, drain 34, body 38 and gate 32 terminals are affixed to the source region 16, drain region 17, body node region 18 and gate electrode 22, respectively. Terminal A, coupled to the body 38, drain 34, and gate 32 terminals, and terminal B, coupled to the source terminal 36, form the input and output of an N+/P type B/G-C diode 10. Although not shown, the connections of the terminals can be easily made on any of the metal layers of MOSFET 30.

The operation of the MOSFET B/G-C diode shown in FIG. 1 takes place in two current regions. In the first current region, the B/G-C diode provides ideal diode characteristics. In the second current region, the B/G-C diode provides ESD protection. In general, the first current region of the BG-C diode corresponds to the functional voltage range from approximately 0 volts to approximately Vdd, wherein Vdd is the power supply voltage. The exponential portion of diode characteristics, though, is typically limited to zero to approximately +/−0.7 volts because of external and parasitic series resistances. The second current region of the B/G-C diode corresponds to the range approximately below zero and above the power supply voltage, Vdd.

For the second current region, ESD protection is provided under two turn-on conditions of the MOSFET B/G-C diode. The first turn-on condition occurs when the voltage of the body 38 exceeds the voltage of the source 36. When this condition occurs, a forward-biased diode attribute allows a current flow from the body terminal to the source terminal.

The second turn-on condition occurs when the voltage at the gate 32 exceeds the threshold voltage. That is, as the signal pad voltage increases, the body voltage and the gate voltage will also increase. When the body voltage increases, the threshold voltage decreases. Thus, when the gate voltage exceeds the threshold voltage, current will flow from the drain terminal to the source terminal.

Thus, for the NFET B/G-C diode 10 (FIG. 1), when a negative pulse is applied to the terminal of the NFET (terminal B), the current is discharged through the P-N diode formed by the body 18 and drain region 17 of the NFET structure. In parallel, as the body voltage increases, the threshold voltage of the MOSFET 30 decreases, creating a dynamic threshold and ideal diode characteristics. As the threshold voltage of the NFET decreases, the gate-coupling of the NFET turns on the NFET in parallel with the diode. A unique aspect of the B/G-C diode is the parallel operation characteristic of the diode and the body and gate coupled MOSFET interaction. The B/G-C diode uses body-coupling to lower the absolute value of the threshold voltage and gate-coupling to turn on the ESD MOSFET element prior to NFET snapback.

A distinguishing aspect of the B/G-C diode as compared to other diodes is the parallel operation of diodic characteristic of the diode and the body 25 and gate coupled MOSFET interaction. That is, the B/G-C diode uses body-coupling to lower the absolute value of the threshold voltage and gate-coupling to turn on the ESD MOSFET element prior to FET snapback.

However, when a positive ESD pulse is applied to the terminal A, the P-N diode formed by the body 18 and source region 16 of the NFET structure is under reverse bias. Thus, the positive ESD protection ability of the structure shown in FIG. 1 is poor.

U.S. Statutory Invention Registration (SIR) No. H1435 to Cherne discloses a MOSFET formed on a dielectric layer having a T shaped gate. FIG. 2 of the SIR shows a top view of conventional N-channel SOI MOSFETs. The conventional N-channel SOI MOSFET 41 shown in FIG. 2 is commonly called a T-gate MOSFET because of the T-shape of gate 42. The T-gate MOSFET 41 has an active region 44 formed on an insulating layer 40. The active region 44 is divided into three regions by T-gate 42, including the source region S, the drain region D and the body-tie region 45. Typically, the T-gate 42 includes a first leg 43A and a second leg 43B. The N-type source/drain regions S and D are located on either side of the first leg 43A and along the lower side of the second leg 43B.

The T-gate configuration has a number of advantages. First, the T-gate configuration provides a body-tie connection to the body/channel region under gate 42. Thus, holes that are generated in the body/channel region under the first leg 43A of gate 42, pass through the P-type region under the second leg 43B, and arrive at the P-type body-tie region 45 where they are collected by the body-tie contact. Thus, the T-gate configuration may reduce or eliminate the substrate floating effects discussed above.

Another advantage of the T-gate configuration is that the second leg 43B eliminates the channel/dielectric interface along the upper side wall of the body/channel region under the first leg 43A. Accordingly, the chance that a parasitic channel will be formed along the upper side wall due to ionizing radiation is reduced or eliminated. The second leg 43B also functions to prevent the silicide layer from connecting the body-tie region 45 and the source region S and drain region D.

In addition, a parasitic NPN bipolar junction transistor is generated by the drain region D, the source drain S, and the p-type region under the first leg 43A, which are used as the collector, the emitter, and the base of the NPN bipolar junction transistor, respectively. Thus, when a positive ESD pulse is applied to the drain region D of the T-gate MOSFET 41 and the source region is grounded, the parasitic NPN bipolar junction transistor is turned on to eliminate the ESD current.

However, when a negative ESD is applied to the drain region D of the T-gate MOSFET 41 and the source region is grounded, the parasitic NPN bipolar junction transistor of the T-gate MOSFET 41 cannot be turned on. Thus, the negative ESD protection ability of the T-gate MOSFET 41 is poor.

### SUMMARY OF THE INVENTION

Accordingly, an object of the present invention is to provide an ESD protection device. The ESD protection device of one embodiment comprises a T-shaped gate and a SOI structure for positive and negative ESD protection. A first-type well is formed on an insulating layer. First and second second-type doped regions are formed on the first-type well. A first body-tie region is formed on the first-type well and is connected to one side of the first and the second second-type doped regions. A polysilicon gate layer is formed on the first-type well and the body-tie region, and is located between the first and the second second-type doped regions. The first first-type doped region is connected to the first body-tie region. The second first-type doped region is formed on the first-type well.

In another embodiment, the ESD protection device provides a p-type well formed on an insulating layer. A first and second n-type doped regions are formed on the p-type well. A first body-tie region is formed on the p-type well and is connected to one side of the first and the second n-type doped regions. A first T-shaped polysilicon gate is formed on the p-type well and the first body-tie region, and is located between the first and the second n-type doped regions. The first T-shaped polysilicon gate comprises a first leg located between the first and the second n-type doped regions and a second leg located on the first body-tie region. The third and a fourth n-type doped regions are formed on the p-type well. The second body-tie region is formed on the p-type well and is connected to one side of the third and the fourth n-type doped regions. The second T-shaped polysilicon gate is formed on the p-type well and the second body-tie region, and is located between the third and the fourth second-type doped regions. The second T-shaped polysilicon gate comprises a third leg located between the third and the fourth n-type doped regions and a fourth leg located on the second body-tie region. The first p-type doped region is connected to the first and the second body-tie regions. The second p-type doped region is formed on the p-type well between the second and the third p-type doped regions.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 is a cross-sectional view of a conventional diode formed on an isolating layer.

FIG. 2 is a top view of conventional N-channel SOI MOSFETs.

FIG. 3A is a top view of an N-channel SOI MOSFETs with a T-gate according to one embodiment of the present invention.

FIG. 3B is a cross-sectional view of FIG. 3A along line AA.

FIG. 4A is a top view of N-channel SOI MOSFETs with an H-gate according to another embodiment of the present invention.

FIG. 5 is a table showing the effect of ESD protection according to the embodiments of the present invention.

### DETAILED DESCRIPTION OF THE INVENTION

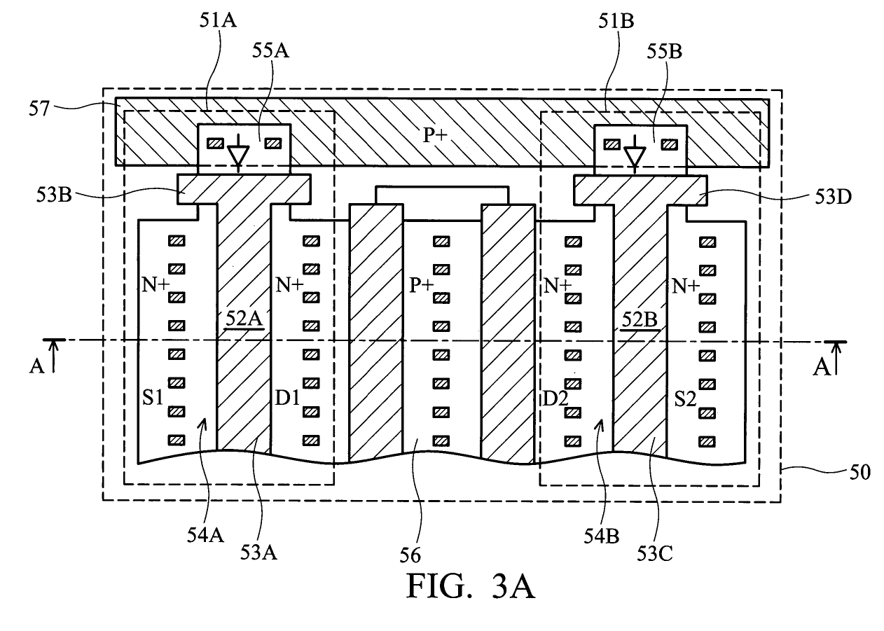

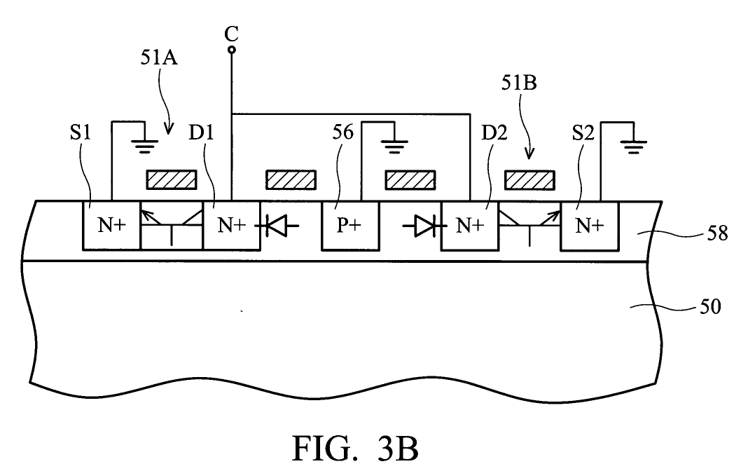

FIG. 3A shows a top view of N-channel SOI MOSFETs with a T-gate according to a first embodiment of the present invention. The T-gate MOSFET 51A has an active region 54A formed on an insulating layer 50. The active region 54A is divided into three regions by T-gate 52A, including the source region S1, the drain region D1 and the p-type body-tie region 55A. Typically, the T-gate 52A includes a first leg 53A and a second leg 53B. The N-type source/drain regions S1 and D1 are located on either side of the first leg 53A and along the lower side of the second leg 53B. The body-tie region 55A is located above the second leg 53B. A p-type body/channel region is located under the first and second legs 53A and 53B. The active region is provided using known techniques. A thin gate oxide layer is provided over the active region, followed by a doped polysilicon gate layer. The doped polysilicon gate layer and the gate oxide layer are selectively etched to form the T-shaped gate 52A. The source and drain regions S1 and D1 are then selectively doped with an N-type dopant (for an N-channel device). A mask is used to define the area that is to be exposed to the N-type dopant. Likewise, the body-tie region 55A is selectively doped with a P-type dopant. Finally, the source region S1, the drain region D1, the body-tie region 55A, and the gate 52A are each covered with a silicide layer to reduce the resistance thereof.

In addition, the T-gate MOSFET 51B has an active region 54B formed on the insulating layer 50. The active region 54B is divided into three regions by T-gate 52B, including the source region S2, the drain region D2 and the body-tie region 55B. Typically, the T-gate 52B includes a first leg 53C and a second leg 53D. In addition, a p-type doped region 56 is formed on the insulating layer 50 and between the drains D1 and D2. Here, P-N junctions are formed between the p-type doped region 56 and the drain region D1 and between the p-type doped region 56 and the drain region D2. In addition, a parasitic NPN bipolar junction transistor is generated by the drain region D1, the source region S1, and the p-type region under the first leg 53A, which are used as the collector, the emitter, and the base of the NPN bipolar junction transistor, respectively. Moreover, a parasitic NPN bipolar junction transistor is generated by the drain region D2, the source region S2, and the p-type region under the first leg 53C, which are used as the collector, the emitter, and the base of the NPN bipolar junction transistor, respectively. In addition, a p-type doped region 57 is coupled to the body-tie regions 55A and 55B.

FIG. 3B shows a cross-sectional view of FIG. 3A along the line AA. When a positive ESD pulse is applied to the terminal C connected to the drain regions D1 and D2, wherein the p-type doped region 56 and the source regions S1 and S2 are grounded, the parasitic NPN bipolar junction transistors of the T-gate MOSFETs 51A and 51B are turned on and the charge accumulating in the semiconductor device will flow to the ground. In addition, when a negative ESD pulse is applied to the terminal C connected to the drain regions D1 and D2, the P-N diodes formed between the p-well 58 and the drain regions D1 and D2 are under forward bias. Thus, the negative ESD pulse passes to the ground through the p-type doped region 56.

Thus, the elements of the semiconductor device are prevented from damage by the positive and negative ESD pulses.

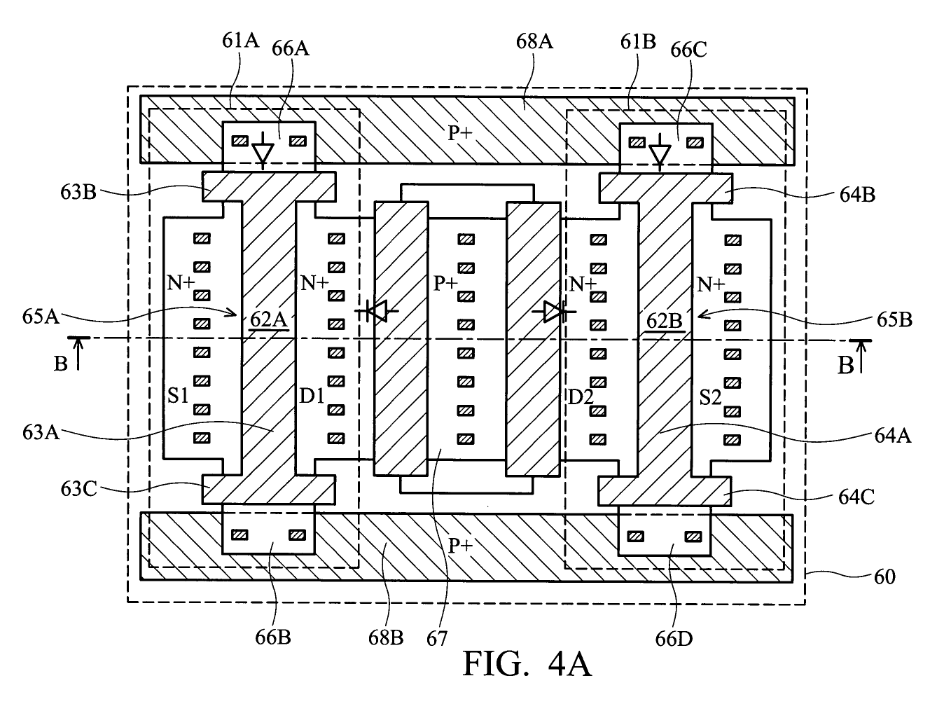

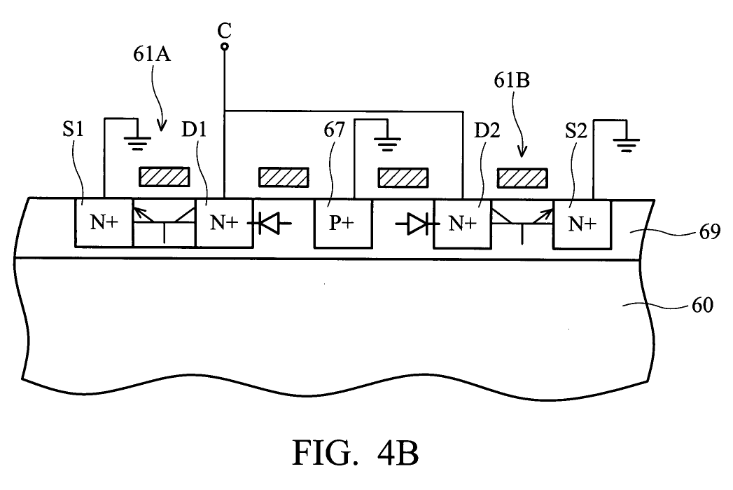

FIG. 4A shows a top view of the N-channel SOI MOSFETs with an H-gate according to a second embodiment of the present invention. The H-gate MOSFET 61A has an active region 65A formed on an insulating layer 60. The active region 65A is divided into four regions by H-gate 62A, including the source region S1, the drain region D1 and the body-tie regions 66A and 66B. Typically, the H-gate 62A includes a first leg 63A, a second leg 63B and a third leg 63C. The N-type source/drain regions S1 and D1 are located on either side of the first leg 63A, and along the lower side of the second leg 63B and the upper side of the third leg 63C. The body-tie region 66A is located above the second leg 63B and the body-tie region 66B is located below the second leg 63C. A p-type body/channel region is located under the first, second and third legs 63A, 63B and 63C. The active region is provided using known techniques. A thin gate oxide layer is provided over the active region, followed by a doped polysilicon gate layer. The doped polysilicon gate layer and the gate oxide layer are selectively etched to form the H-shaped gate 62A. The source and drain regions S1 and D1 are then selectively doped with an N-type dopant (for an N-channel device). A mask is used to define the area that is to be exposed to the N-type dopant. Likewise, the body-tie regions 66A and 66B are selectively doped with a P-type dopant. Finally, the source region S1, the drain region D1, the body-tie regions 66A and 66B, and the gate 52A are each covered with a silicide layer to reduce the resistance thereof.

In addition, the H-gate MOSFET 61B has an active region 65B formed on the insulating layer 60. The active region 65B is divided into four regions by H-gate 62B, including the source region S2, the drain region D2 and the body-tie regions 66C and 66D. Typically, the H-gate 62B includes a first leg 64A, a second leg 64B and a third leg 64C. The N-type source/drain regions S1 and D1 are located on either side of the first leg 64A, and along the lower side of the second leg 64B and the upper side of the third leg 64C. The body-tie region 66C is located above the second leg 64B and the body-tie region 66D is located below the third leg 64C. A p-type body/channel region is located under the first, second and third legs 64A, 64B and 64C.

In addition, a p-type doped region 67 is formed on the insulating layer 60 and between the drains D1 and D2. Here, P-N junctions are formed between the p-type doped region 67 and the drain region D1 and between the p-type doped region 67 and the drain region D2. In addition, a parasitic NPN bipolar junction transistor is generated by the drain region D1, the source region S1, and the p-type region under the first leg 63A, which are used as the collector, the emitter, and the base of the NPN bipolar junction transistor, respectively. Moreover, another parasitic NPN bipolar junction transistor is generated by the drain region D2, the source region S2, and the p-type region under the first leg 64A, which are used as the collector, the emitter, and the base of the NPN bipolar junction transistor, respectively. In addition, p-type doped regions 68A and 68B are coupled to the body-tie regions 66A and 66C, and the body-tie regions 66B and 66D, respectively.

FIG. 4B shows a cross-sectional view of FIG. 4A along the line BB. When a positive ESD pulse is applied to the terminal C connected to the drain regions D1 and D2, wherein the p-type doped region 67 and the source regions S1 and S2 are grounded, the parasitic NPN bipolar junction transistors of the H-gate MOSFETs 61A and 61B are turned on and the charge accumulating in the semiconductor device will flow to the ground. In addition, when a negative ESD pulse is applied to the terminal C connected to the drain regions D1 and D2, the P-N diodes formed between the p-well 69 and the drain regions D1 and D2 are under forward bias. Thus, the negative ESD pulse passes to the ground through the p-type doped region 67.

Thus, the elements of the semiconductor device are prevented from being damaged by the positive and negative ESD pulses.

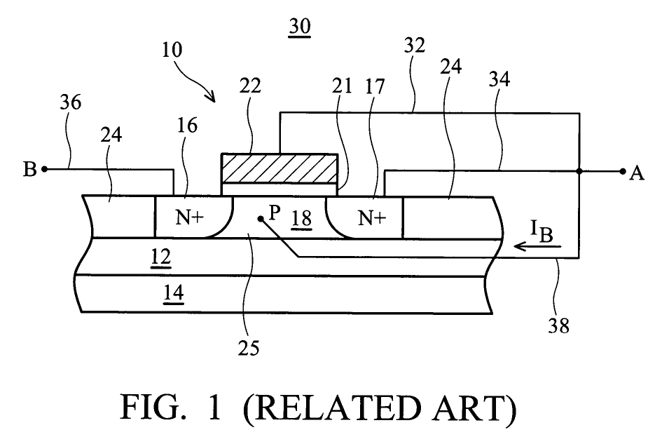

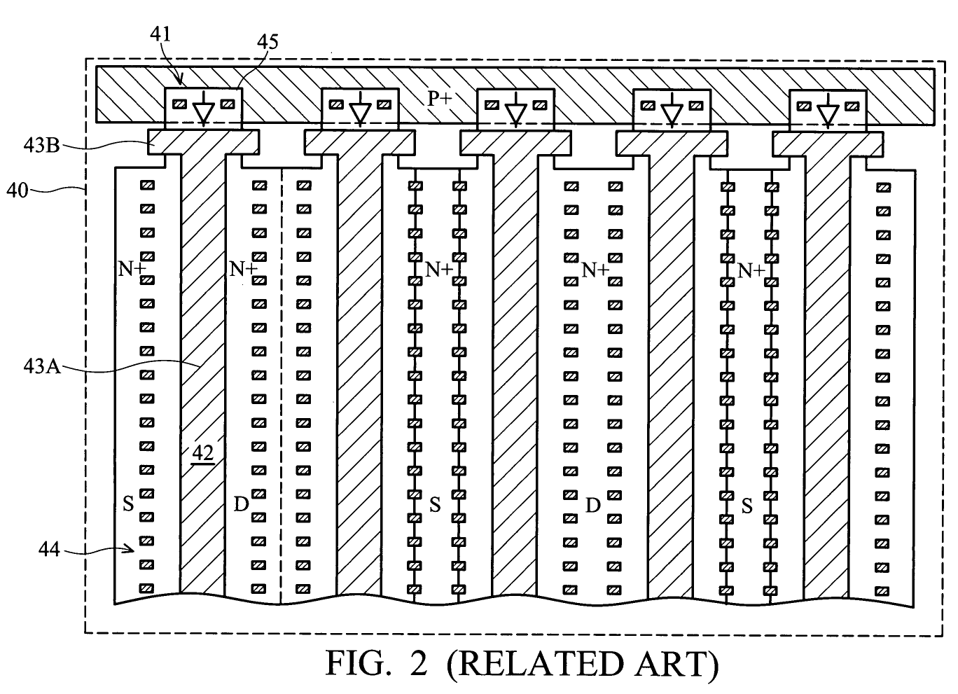

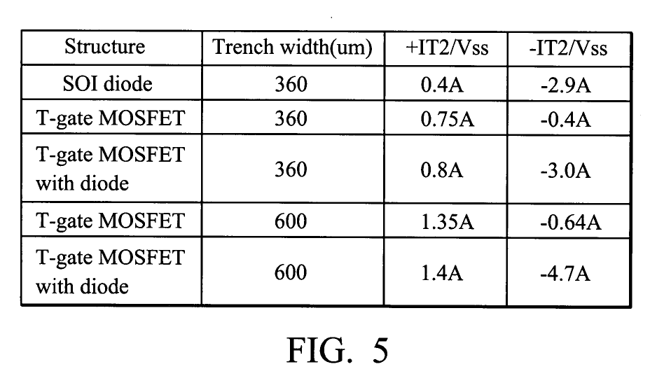

FIG. 5 shows the effect of ESD protection according to the first embodiment of the present invention. The test signal is a square wave with a period of 100 ns. The positive and negative tolerable currents of the conventional diode with the trench width of 360 um shown in FIG. 1 are 0.4A and −2.9A when the test signal is provided to the terminal B and the other terminals are grounded. The positive and negative tolerable currents of the conventional N-channel SOI MOSFET with the trench width of 360 um shown in FIG. 2 are 0.75A and −0.4A when the test signal is provided to the drain region of the MOSFET 41 and the other terminals are grounded. The positive and negative tolerable currents of the conventional N-channel SOI MOSFET with the trench width of 600 um shown in FIG. 2 are 1.35A and −0.64A. However, the ESD protection device of the present invention has improved ESD protection ability. In FIG. 5, the positive and negative tolerable currents of the T-gate N-channel SOI MOSFET with the trench width of 360 um shown in FIG. 3A are 0.8A and −3.0A, and the positive and negative tolerable currents of the T-gate N-channel SOI MOSFET with the trench width of 600 um are 1.4A and −4.7A when the test signal is provided to the drain region D1 of the MOSFET 51A and the other terminals are grounded.

According to FIG. 5, the ESD protection device according to the present invention improves positive ESD protection of the convention diode formed on an insulating layer shown in FIG. 1 and negative ESD protection of the convention N-channel SOI MOSFET shown in FIG. 2.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. An ESD protection device, comprising:
an insulating layer;
a first-type well formed on the insulating layer;
a first and a second second-type doped regions formed on the first-type well;
a first body-tie region formed on the first-type well and connected to one side of the first and the second second-type doped regions;
a polysilicon gate layer formed on the first-type well and the body-tie region, and located between the first and the second second-type doped regions;
a first first-type doped region connected to the first body-tie region; and
a second first-type doped region formed on the first-type well.

2. The ESD protection device as claimed in claim 1, wherein the first-type is p-type, and the second-type is n-type.

3. The ESD protection device as claimed in claim 1, wherein the body-tie region is a p-type doped region.

4. The ESD protection device as claimed in claim 1, wherein the polysilicon gate layer is a T-shaped gate.

5. The ESD protection device as claimed in claim 4, wherein the polysilicon gate layer comprises a first leg and a second leg, the first leg is located between the first and the second second-type doped regions, and the second leg is located on the first body-tie region.

6. The ESD protection device as claimed in claim 1, further comprising a second body-tie region formed on the first-type well and connected to another side of the first and the second second-type doped regions.

7. The ESD protection device as claimed in claim 6, further comprising a third first-type doped region connected to the second body-tie region.

8. The ESD protection device as claimed in claim 6, wherein the polysilicon gate layer is an H-shaped gate.

9. The ESD protection device as claimed in claim 7, wherein the polysilicon gate layer comprises a first leg, a second leg and a third leg, the first leg is located between the first and the second second-type doped regions, the second leg is located on the first body-tie region, and the third leg is located on the second body-tie region.

10. An ESD protection device, comprising:
an insulating layer;
a first-type well formed on the insulating layer;
a first and a second second-type doped regions formed on the first-type well;
a first body-tie region formed on the first-type well and connected to one side of the first and the second second-type doped regions;
a first polysilicon gate layer formed on the first-type well and the first body-tie region, and located between the first and the second second-type doped regions;
a third and a fourth second-type doped regions formed on the first-type well;
a second body-tie region formed on the first-type well and connected to one side of the third and the fourth second-type doped regions;
a second polysilicon gate layer formed on the first-type well and the second body-tie region, and located between the third and the fourth second-type doped regions;
a first first-type doped region connected to the first and the second body-tie regions; and
a second first-type doped region formed on the first-type well between the second and the third second-type doped regions.

11. The ESD protection device as claimed in claim 10, wherein the first-type is p-type, and the second-type is n-type.

12. The ESD protection device as claimed in claim 10, wherein the first and second body-tie regions are p-type doped regions.

13. The ESD protection device as claimed in claim 10, wherein the first polysilicon gate layer and the second polysilicon gate layer are T-shaped gates.

14. The ESD protection device as claimed in claim 13, wherein the first polysilicon gate layer comprises a first leg and a second leg, and the second polysilicon gate layer comprises a third leg and a fourth leg, the first leg is located between the first and the second second-type doped regions and the second leg is located on the first body-tie region, the third leg is located between the third and the fourth second-type doped regions, and the fourth leg is located on the second body-tie region.

15. The ESD protection device as claimed in claim 10, further comprising a third body-tie region formed on the first-type well and connected to another side of the first and the second second-type doped regions.

16. The ESD protection device as claimed in claim 15, further comprising a fourth body-tie region formed on the first-type well and connected to another side of the third and the fourth second-type doped regions.

17. The ESD protection device as claimed in claim 16, further comprising a third first-type doped region connected to the third and the fourth body-tie regions.

18. The ESD protection device as claimed in claim 17, wherein the first and second polysilicon gate layers are H-shaped gates.

19. The ESD protection device as claimed in claim 18, wherein the first polysilicon gate layer comprises a first leg, a second leg and a third leg, the second polysilicon gate layer comprises a fourth leg, a fifth leg and a sixth leg, the first leg is located between the first and the second second-type doped regions, the second leg is located on the first body-tie region and the third leg is located on the third body-tie region, the fourth leg is located between the third and the fourth second-type doped regions, the fifth leg is located on the second body-tie region, and the sixth leg is located on the fourth body-tie region.
